(19) United States
(12) Patent Application Publication
(10) Pub. No.: US 2019/0088794 A1
(43) Pub. Date: Mar. 21, 2019

(54) THIN FILM TRANSISTOR ARRAY PANEL AND DISPLAY DEVICE INCLUDING THE SAME

(71) Applicant: Samsung Display Co., Ltd., Yongin-si (KR)

(72) Inventors: Jae Woo JEONG, Suwon-si (KR); In Cheol KO, Hwaseong-si (KR); Jong Jun BAEK, Seoul (KR)

(21) Appl. No.: 15/919,419

(22) Filed: Mar. 13, 2018

(30) Foreign Application Priority Data
Sep. 18, 2017 (KR) 10-2017-0119654

(51) Int. Cl. H01L 29/786; H01L 21/02; H01L 27/12; H01L 27/32; H01L 29/417; G09G 3/3208

(52) U.S. Cl. CPC H01L 29/78696; H01L 21/02667; H01L 27/1274; H01L 27/1248; G09G 3/3208; H01L 27/3225; H01L 27/1255; H01L 27/1237; H01L 29/41733; H01L 27/1288

(57) ABSTRACT

A display device includes: a substrate including a display area at which an image is displayed with light; and a switching element on the substrate in the display area thereof. The switching element includes: a semiconductor layer; a first gate electrode; a second gate electrode connected to the first gate electrode; a fluorine-doped first insulating layer between the first gate electrode and semiconductor layer; and a fluorine-doped second insulating layer between the second gate electrode and the semiconductor layer.

This application claims priority to Korean Patent Application No. 10-2017-0119654 filed on Sep. 18, 2017, and all the benefits accruing therefrom under 35 U.S.C. § 119, the content of which in its entirety is incorporated herein by reference.

### BACKGROUND

### (a) Field

The present disclosure relates to a thin film transistor array panel and a display device including the same, and in detail, relates to a thin film transistor array panel in which an insulating layer on or under a semiconductor layer is doped with fluorine.

### (b) Description of the Related Art

Among flat panel displays, an organic light emitting display (“OLED”) device displays an image by using an organic light emitting element generating light by a recombination an electron and a hole. The organic light emitting display device has merit in that a response speed thereof is relatively fast and simultaneously power consumption is relatively low.

### SUMMARY

Exemplary embodiments provide a thin film transistor array panel with a reduced hydrogen content at an interface between an insulating layer and a semiconductor layer and with improved reliability, and a display device including the same.

A display device according to an exemplary embodiment of the invention includes: a substrate including a display area at which an image is displayed with light; and a switching element on the substrate in the display area thereof. The switching element includes: a semiconductor layer; a first gate electrode; a second gate electrode connected to the first gate electrode; a fluorine-doped first insulating layer between the first gate electrode and semiconductor layer; and a fluorine-doped second insulating layer between the second gate electrode and the semiconductor layer.

The fluorine-doped first insulating layer and the fluorine-doped second insulating layer may include a gate contact hole commonly defined therein, and the second gate electrode may be connected to the first gate electrode at the gate contact hole.

An upper region of the fluorine-doped first insulating layer which is adjacent to the semiconductor layer may include fluorine.

A maximum thickness of the upper region of the fluorine-doped first insulating layer which includes the fluorine may be about 20% or more of an entire thickness of the fluorine-doped first insulating layer.

A lower region of the fluorine-doped second insulating layer which is adjacent to the semiconductor layer may include fluorine.

A maximum thickness of the lower region of the fluorine-doped second insulating layer which includes the fluorine may be about 20% to about 100% of an entire thickness of the fluorine-doped second insulating layer.

The first gate electrode and the second gate electrode connected to each other may overlap each other via the semiconductor layer disposed therebetween.

A hydrogen content of the semiconductor layer of the switching element may be less than about 3 mol %.

The fluorine-doped first insulating layer and the fluorine-doped second insulating layer may each include silicon oxide or silicon nitride.

A doped region of the fluorine-doped first insulating layer and the fluorine-doped second insulating layer may include fluorine, and each of the doped regions may include a silicon-hydrogen bond and a silicon-fluorine bond.

A display device according to another an exemplary embodiment of the invention includes: a substrate including a display area at which an image is displayed with light; a switching element on the substrate in the display area thereof, the switching element including: a semiconductor layer including a source region, a channel region and a drain region; a first gate electrode; a second gate electrode connected to the first gate electrode; a fluorine-doped first insulating layer between the first gate electrode and the semiconductor layer; a fluorine-doped second insulating layer between the second gate electrode and the semiconductor layer; and a source electrode and a drain electrode connected to the source region and the drain region of the semiconductor layer, respectively; and a first electrode of a light-generating element, connected to the drain electrode of the switching element.

The fluorine-doped first insulating layer and the fluorine-doped second insulating layer may include a gate contact hole commonly defined therein, and the second gate electrode may be connected to the first gate electrode at the gate contact hole commonly defined in the fluorine-doped first and second insulating layers.

An upper region of the fluorine-doped first insulating layer which is adjacent to the semiconductor layer may include fluorine.

A maximum thickness of the upper region of the fluorine-doped first insulating layer which includes the fluorine may be about 20% or more of an entire thickness of the fluorine-doped first insulating layer.

A lower region of the fluorine-doped second insulating layer which his adjacent to the semiconductor layer may include fluorine.

A maximum thickness of the lower region of the fluorine-doped second insulating layer which include the fluorine may be about 20% to about 100% of an entire thickness of the fluorine-doped second insulating layer.

The first gate electrode and the second gate electrode connected to each other may overlap each other via the semiconductor layer disposed therebetween.

A hydrogen content of the semiconductor layer of the switching element may be less than about 3 mol %.

A second electrode of the light-emitting element which overlaps the first electrode thereof, and an emission layer of the light-emitting element between the first electrode and the second electrode thereof, may be further included in the display device.

A doped region of the fluorine-doped first insulating layer and the fluorine-doped second insulating layer may include fluorine, and each of the doped regions may include a silicon-hydrogen bond and a silicon-fluorine bond.

According to one or more exemplary embodiment, the thin film transistor array panel with a minimized hydrogen content at a layer interface with the semiconductor layer and the display device including the same, has improved reliability.

### BRIEF DESCRIPTION OF THE DRAWINGS

The above and other advantages and features of this disclosure will become more apparent by describing in further detail exemplary embodiments thereof with reference to the accompanying drawings, in which:

FIG. 1 is an enlarged schematic cross-sectional view of an exemplary embodiment of a thin film transistor array panel according to the invention.

FIG. 2 is an enlarged cross-sectional view of an exemplary embodiment of a stacked core structure of a thin film transistor array panel according to the invention.

FIGS. 3A and 3B are cross-sectional views showing an exemplary embodiment of a silicon-hydrogen bond and silicon-fluorine bond inside a material film before and after doping, respectively.

FIG. 4 is an enlarged top plan view of an exemplary embodiment of a display device according to the invention.

FIG. 5 is a cross-sectional view taken along line V-V of FIG. 4.

FIG. 6 is a cross-sectional view taken along line VI-VI of FIG. 4.

### DETAILED DESCRIPTION

Hereinafter, the invention will be described more fully with reference to the accompanying drawings, in which exemplary embodiments of the invention are shown. As those skilled in the art would realize, the described embodiments may be modified in various different ways, all without departing from the spirit or scope of the invention.

Parts that are irrelevant to the description will be omitted to clearly describe the invention, and the same elements will be designated by the same reference numerals throughout the specification.

In addition, the size and thickness of each configuration shown in the drawings are arbitrarily shown for better understanding and ease of description, but the invention is not limited thereto. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being related to another element such as being “on” another element, it can be directly on the other element or intervening elements may also be present. In contrast, when an element is referred to as being related to another element such as being “directly on” another element, there are no intervening elements present.

Further, in the specification, the word “on” or “above” means positioned on or below the object portion, and does not necessarily mean positioned on the upper side of the object portion based on a gravitational direction.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. In addition, unless explicitly described to the contrary, the word “comprise” and variations such as “comprises” or “comprising” will be understood to imply the inclusion of stated elements but not the exclusion of any other elements.

Further, in the specification, the phrase “in a plan view” means when an object portion is viewed from above, and the phrase “in a cross-section” means when a cross-section taken by vertically cutting an object portion is viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In an organic light emitting display device, a thin film transistor to control an operation of each pixel to generate and/or emit light for displaying an image is disposed on a substrate. The thin film transistor includes a semiconductor layer, a source electrode, a drain electrode, a gate electrode, etc. In this case, a dual gate thin film transistor in which two gate electrodes are included in one thin film transistor may be used as the thin film transistor to control the operation and/or light emission of each pixel within the display device, such as in a display area thereof, without being limited thereto.

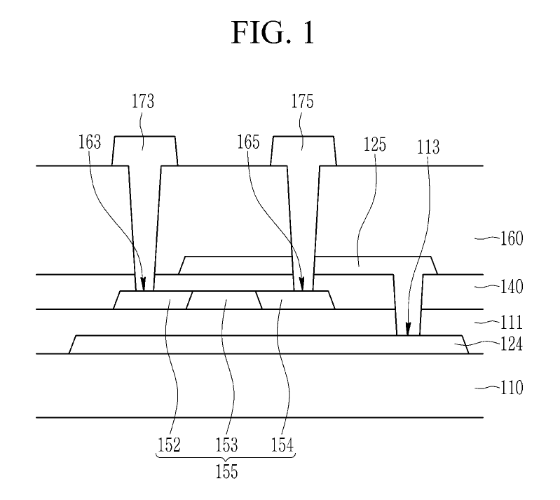

Now, a thin film transistor array panel according to an exemplary embodiment of the invention will be described based on a schematic cross-sectional view. FIG. 1 is an enlarged schematic cross-sectional view of an exemplary embodiment of a thin film transistor array panel according to the invention.

A display device displays an image with light. The display device includes a display area at which the image is displayed and a non-display area at which the image is not displayed. The non-display area may surround the display area, without being limited thereto. The display device may include a display panel in which an image is generated and displayed with light. The light may be generated within the display panel or light generated external to the display panel may be provided thereto. The display panel may include a thin film transistor array panel.

Referring to FIG. 1, a thin film transistor array panel used in a display device according to an exemplary embodiment of the invention includes a (base) substrate 110 including a display area and a non-display area, a first gate electrode 124 positioned on the substrate 110, a first insulating layer 111 positioned on the first gate electrode, a semiconductor layer 155 positioned on the first insulating layer 111, a second insulating layer 140 positioned on the semiconductor layer 155, and a second gate electrode 125 positioned on the second insulating layer, where the first gate electrode 124 and the second gate electrode 125 are connected to each other. That is, the first insulating layer 111 and the second insulating layer 140 positioned between the first gate electrode 124 and the second gate electrode 125 have a gate contact hole 113 defined therein, and the first gate electrode 124 and the second gate electrode 125 are connected to each other at and/or through the gate contact hole 113.

The semiconductor layer 155 includes a source region 152, a channel region 153 and a drain region 154. Also, an interlayer insulating layer 160 on the second gate electrode 125 is included, and the interlayer insulating layer 160 and the second insulating layer 140 have a first contact hole 163 defined therein and a second contact hole 165 defined therein. A source electrode 173 and a drain electrode 175 are positioned on the interlayer insulating layer 160, and are respectively connected to the source region 152 and the drain region 154 of the semiconductor layer 155 through the first contact hole 163 and the second contact hole 165.

The above-described structure includes layers at a thin film transistor of the thin film transistor array panel. The thin film transistor may be disposed in the display area of the substrate 110, without being limited thereto. Insulating layers disposed at the thin film transistor may extend therefrom to other portions of the substrate 110, such as to another location in the display area or to the non-display area of the substrate 110.

In the invention, the first insulating layer 111 and the second insulating layer 140 may include a silicon oxide or a silicon nitride. The first insulating layer 111 and the second insulating layer 140 are doped with fluorine. The fluorine doping of the first insulating layer 111 and the second insulating layer 140 reduces a hydrogen concentration in the semiconductor layer 155, the first insulating layer 111 and the second insulating layer 140, thereby reliability of an element including such layers is improved.

As shown in FIG. 1, the thin film transistor array panel according to an exemplary embodiment of the invention is a structure of a dual gate electrode including the first gate electrode 124 and the second gate electrode 125 connected thereto. Accordingly, a charge interface trap formed between the gate electrode and the semiconductor layer has two parts. That is, because both of the interface between the semiconductor layer 155 and the first gate electrode 124 and the interface between the semiconductor layer 155 and the second gate electrode 125 become the charge interface trap, the hydrogen concentration must be minimized at both interfaces of the semiconductor layer 155 to improve the reliability of the element. That is, the hydrogen concentration of the insulating layer adjacent to the semiconductor layer 155 decreases in a direction toward the semiconductor layer 155, along a thickness of the insulating layer.

In the thin film transistor array panel according to the present exemplary embodiment, as both of the first insulating layer 111 and the second insulating layer 140 in contact with the semiconductor layer 155 are doped with fluorine, the concentration of hydrogen decreases in the film, thereby improving the reliability of the display device element including such layers.

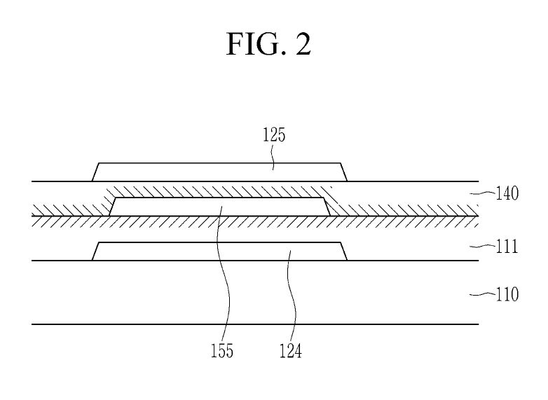

In the present exemplary embodiment, both of the first insulating layer 111 and the second insulating layer 140 may be doped with fluorine, however only a part of the region of the first insulating layer 111 and the second insulating layer 140 in contact with the semiconductor layer 155 may be doped with fluorine. Hereinafter, it is described in more detail with reference to FIG. 2.

FIG. 2 is an enlarged cross-sectional view of a simplified representation of the structure of the substrate 110, the first gate electrode 124, the first insulating layer 111, the semiconductor layer 155, the second insulating layer 140 and the second gate electrode 125 described above with respect to FIG. 1. Other layers in FIG. 1 are omitted for convenience of explanation of FIG. 2. Referring to FIG. 2, an upper region (a hatched area) of the first insulating layer 111 closest to the semiconductor layer 155 and a lower region (a hatched area) of the second insulating layer 140 closest to the semiconductor layer 155 may be the region doped with fluorine.

In this case, a maximum thickness of the first insulating layer 111 at the fluorine doping region of the first insulating layer 111 may be about 20% or more of an entire thickness of the first insulating layer 111. This will be described in detail later. At the doped region of the first insulating layer 111, the doped fluorine removes a dangling bond of silicon and reduces the hydrogen content in the material film forming the first insulating layer 111 by replacing the silicon-hydrogen bond with a silicon-fluorine bond. If the thickness of the fluorine doping region is less than 20% of the total thickness of the first insulating layer 111, such effect may not be sufficient. In an exemplary embodiment, the first insulating layer 111 may be entirely doped with fluorine, such that an entire thickness of the first insulating layer 111 is doped with fluorine.

The fluorine doping region of the second insulating layer 140 may be the lower region adjacent to the semiconductor layer 155, and a maximum thickness of this region may be about 20% to about 100% of an entire thickness of the second insulating layer 140.

In an exemplary embodiment of a method of manufacturing a display device, fluorine doping is performed from the top of the first insulating layer 111 and the second insulating layer 140, so it is possible to adjust the doped depth from the top by adjusting the acceleration voltage at which fluorine is injected. However, since the finally-formed second insulating layer 140 is doped in the lower region of the material layer thereof and because the fluorine implantation needs to be performed from the top of the material layer thereof, an entirety of the second insulating layer 140 may be doped during the doping process. In an exemplary embodiment, an entirety of a portion of the second insulating layer 140 at the semiconductor layer 155 may be fluorine-doped, while a remaining portion extended further than the semiconductor layer 155 may be only partially doped. In an alternative embodiment, an entirety of the portion at the semiconductor layer 155 and an entirety of the remaining portion of the second insulating layer 140 may be fluorine-doped.

As above-described, when doping fluorine to the first insulating layer 111 and the second insulating layer 140, fluorine combines with the dangling bond of silicon-hydrogen included in the material film for forming such layer such as to remove such dangling bond, and as result, a phenomenon in which hydrogen is combined with silicon in the material film is reduced or effectively prevented. Also, the silicon-hydrogen bond in the material film for forming the first insulating layer 111 and the second insulating layer 140 is replaced with the silicon-fluorine bond such that the hydrogen content in the material film may be minimized.

That is, when the semiconductor layer 155 includes a crystalline silicon, a process of crystallizing amorphous silicon material after forming the amorphous silicon material layer is performed. In this case, in the crystallizing process, when hydrogen in the semiconductor layer 155 is over a certain content, since the above-described material film is adjacent to the semiconductor layer 155 in the process of the crystallization, minimizing the hydrogen concentration in the material film is important.

For this purpose, a process of removing hydrogen in the material film having the silicon-hydrogen bond is performed before the crystallizing of the semiconductor layer 155. However, the semiconductor layer 155, the first insulating layer 111 and the second insulating layer 140 all include silicon, and a plurality of dangling bonds of which the silicon is not combined with other atoms exist. As hydrogen is combined with the dangling bonds of silicon, a problem that the hydrogen remains without being removed in the dehydrogenation process will occur in the semiconductor layer 155, the first insulating layer 111 and/or the second insulating layer 140.

In this case, hydrogen is removed in a direction away from the substrate 110. Here, while hydrogen existing in the first insulating layer 111 is removed in the direction away from the substrate 110, hydrogen passes through the semiconductor layer 155 and a problem that hydrogen is trapped in the semiconductor layer 155 occurs. Accordingly, sufficiently removing hydrogen of the semiconductor layer 155 in the dehydrogenation process may be difficult.

However, in one or more exemplary embodiment of the thin film transistor array panel according to the invention, fluorine is doped to the first insulating layer 111 and the second insulating layer 140 each adjacent to the semiconductor layer 155. This fluorine-doping removes the dangling bond of silicon included in the first insulating layer 111 and the second insulating layer 140 so that hydrogen is not trapped in the semiconductor layer 155.

Also, since the silicon-fluorine bond is stronger than the silicon-hydrogen bond, the silicon-hydrogen bond in the film is replaced with the silicon-fluorine bond by the fluorine doping. Accordingly, the hydrogen content in the material film for forming the first insulating layer 111 and the second insulating layer 140 may be minimized.

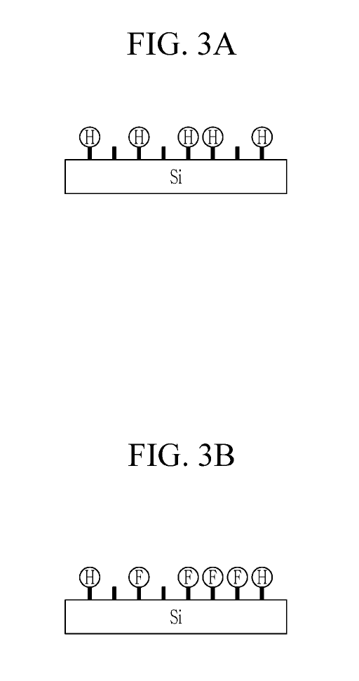

FIG. 3A is a cross-sectional view showing a silicon-hydrogen bond inside a material film before doping and FIG. 3B is a cross-sectional view showing a silicon-fluorine bond inside the material film after doping.

That is, referring to FIG. 3A, silicon-hydrogen is bonded before the fluorine doping and a plurality of dangling bonds exist. However, referring to FIG. 3B, a part of the silicon-hydrogen bond in the un-doped material film is replaced with the silicon-fluorine bond after the fluorine doping such that the overall hydrogen content in the material film is reduced and the number of dangling bonds within the material film is also reduced (e.g., three dangling bonds at which the silicon (Si) is not combined with an atom in FIG. 3A is reduced to two dangling bonds in FIG. 3B). The dangling bonds are represented by the bars protruded from the silicon (Si) film layer in FIGS. 3A and 3B, without having an atom (F or H) attached thereto.

The replacement of the silico-hydrogen bond occurs due to a combination energy (565 kilojoule per mole (kJ/mol)) of silicon-fluorine being larger than a combination energy (317 kJ/mol) of silicon-hydrogen.

In this case, fluorine doped in the upper portion of the first insulating layer 111 also performs a function of a trap site of hydrogen. That is, in the dehydrogenation process of a conventional display device, when hydrogens removed from the lower portion of the first insulating layer 111 move to the semiconductor layer 155 and are fixed to the semiconductor layer 155, the hydrogen concentration of the semiconductor layer 155 is undesirably increased.

However, in one or more exemplary embodiment of the invention, due to fluorine doped to the upper portion of the first insulating layer 111, diffusion of hydrogen to the semiconductor layer 155 is reduced or effectively prevented, and hydrogen is confined within the first insulating layer 111 (e.g., below the upper doped portion thereof). Accordingly, since hydrogen is confined within the first insulating layer 111, the overall concentration of hydrogen may be minimized inside the semiconductor layer 155. Therefore, in one or more exemplary embodiment, the hydrogen content of the semiconductor layer 155 may be less than about 3 mol % relative to a total mol % of the semiconductor layer 155.

This is also applied to the second insulating layer 140. As fluorine of the second insulating layer 140 traps therein hydrogen removed from the semiconductor layer 155, the overall hydrogen content of the semiconductor layer 155 may be reduced.

In this process, the fluorine doping regions of the first insulating layer 111 and the second insulating layer 140 fix the hydrogen therein such that diffusion of hydrogen into the semiconductor layer 155 is reduced or effectively prevented. However, since the entire fluorine doping region forms a part of the first insulating layer 111 and a part of the second insulating layer 140, respectively, and since most of the silicon-hydrogen bonds are substituted by the fluorine doping, the hydrogen content is also reduced within the first insulating layer 111 and the second insulating layer 140. In an exemplary embodiment, for example, the hydrogen content of the respective insulating layer in which the fluorine doping is not doped is about 6 mol % or more, but the hydrogen content of the respective insulating layer may be about 4 mol % or less after applying the fluorine doping thereto.

In one or more exemplary embodiment of the invention, because the process for the crystallization of the semiconductor layer 155 is executed at the temperature of about 500 degrees Celsius or less, fluorine included in the first insulating layer 111 and the second insulating layer 140 is not diffused into an entirety of the respective layer and may be positioned in the doping region of such respective layer.

That is, as above-described, as one or more exemplary embodiment of the thin film transistor array panel according to the invention includes a dual gate structure and fluorine is doped in the insulating layer respectively between the semiconductor layer and each of the gate electrodes, the overall hydrogen content within the semiconductor layer 155 and the respectively insulating layer is reduced. Accordingly, reliability of the display device element including the semiconductor layer may be secured, and a phenomenon where the film of the semiconductor layer is broken in the crystallization process of the semiconductor layer is reduced or effectively prevented.

Next, a display device including the thin film transistor array panel according to an exemplary embodiment of the invention will be described with reference to accompanying drawings.

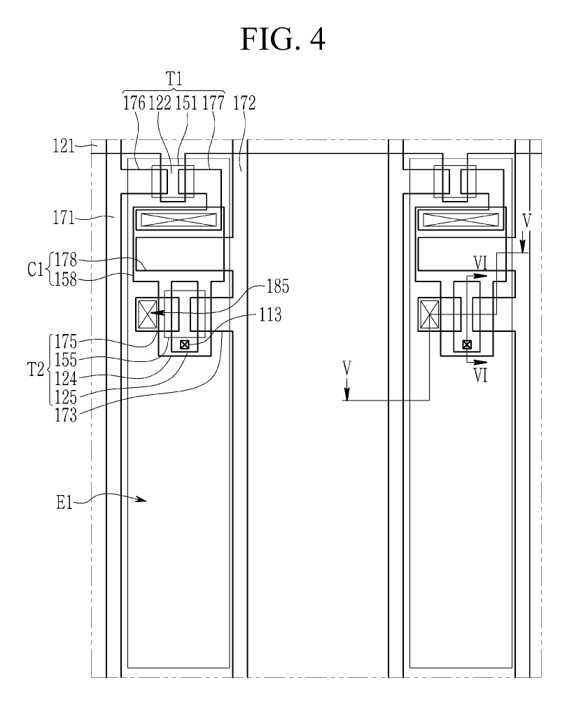

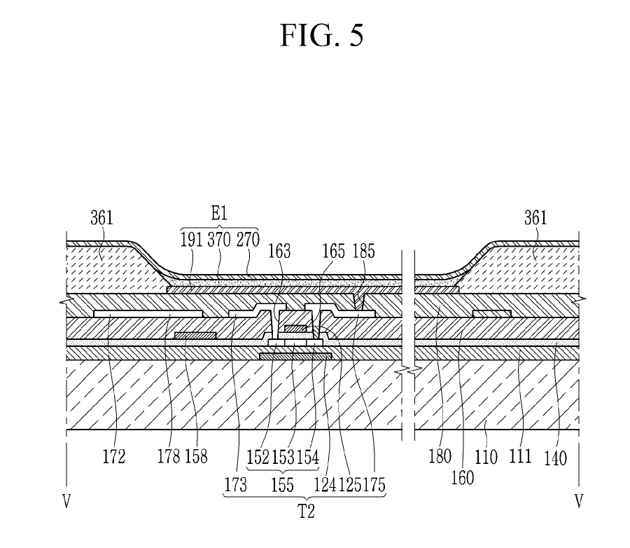

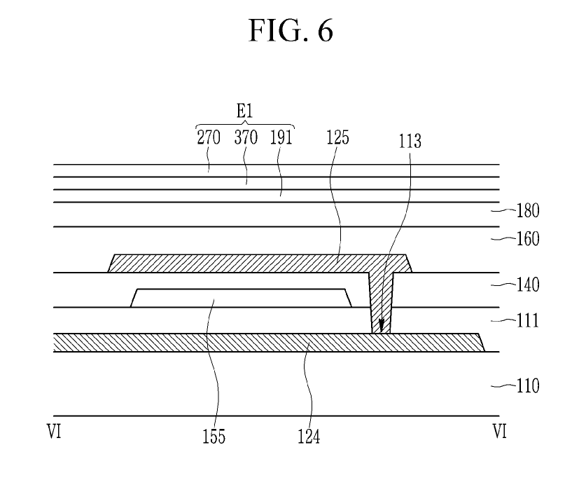

FIG. 4 is an enlarged top plan view of an exemplary embodiment of a display device according to the invention. FIG. 5 is a cross-sectional view taken along line V-V of FIG. 4. FIG. 6 is a cross-sectional view taken along line VI-VI of FIG. 4.

FIG. 4 shows an active matrix (“AM”) light emitting display device of a 2Tr-1Cap structure in which each pixel of the display area includes two switching elements such as two thin film transistors (“TFT”) T1 and T2 and one capacitive element C1, however the invention and the present exemplary embodiment are not limited thereto. That is, one or more exemplary embodiment of the invention may be applied to a display device of a 7TR-1Cap structure in which each pixel includes seven thin film transistors and one capacitive element.

That is, the light emitting display device may have three or more thin film transistors and two or more capacitors in one pixel, and may have various other element structures including separate wires connected to the thin film transistors and/or the capacitive element.

Referring to FIG. 4 and FIG. 5, the display device according to the present exemplary embodiment includes a switching thin film transistor T1, a driving thin film transistor T2, a capacitive element C1, and a light-emitting element E1 disposed or formed in each of a plurality of pixels of a substrate (refer to 110 of FIG. 1 and FIG. 2). The display device includes a gate line 121 having a length disposed along a first direction, and a data line 171 and a common power line 172 that are each insulated from and cross the gate line 121 by having a length disposed along a second direction which crosses the first direction.

The display device and elements thereof may be disposed in a plane parallel to a plane defined by the first and second directions which cross each other (e.g., horizontal and vertical directions in FIG. 4). A thickness of the display device and elements thereof may be taken in a third direction which crosses each of the first and second directions (e.g., vertical in FIG. 5 and FIG. 6).

In an exemplary embodiment, each pixel may be defined by a boundary of the gate line 121, the data line 171 and the common power line 172, but the invention is not limited thereto. The pixel may be a basic or minimum unit of the display device at which the image is displayed with light.

The organic light emitting element E1 includes a pixel electrode 191, a (light) emission layer 370 disposed or formed on the pixel electrode 191, and a common electrode 270 formed on the emission layer 370.

Here, the pixel electrode 191 is an anode as a hole injection electrode, and the common electrode 270 is a cathode as an electron injection electrode. However, the invention is not limited thereto, and the pixel electrode 191 may be the cathode and the common electrode 270 may be the anode according to the driving method of the light emitting display device.

The emission layer 370 may include an organic (light) emission layer, the injected holes and electrons are combined with each other so as to form excitons, and when the excitons drop from an excited state to a ground state, the emission of light occurs. Also, the emission layer 370 may include a quantum dot.

The capacitive element C1 includes a pair of capacitive plates 158 and 178 disposed via the interlayer insulating layer 160 interposed therebetween. Here, the interlayer insulating layer 160 becomes a dielectric material. A capacitance is determined by (electrical) charges charged to the capacitive element C1 and a voltage between the pair of capacitive plates 158 and 178.

The switching thin film transistor T1 includes a switching semiconductor layer 151, a switching gate electrode 122, a switching source electrode 176 and a switching drain electrode 177. The driving thin film transistor T2 includes a driving semiconductor layer 155, a first gate electrode 124, a second gate electrode 125 connected to the first gate electrode 124, a driving source electrode 173 and a driving drain electrode 175.

The switching thin film transistor T1 is used as a switching element for controlling the pixel to generate and emit light. The switching gate electrode 122 is connected to the gate line 121 and the switching source electrode 176 is connected to the data line 171. The switching drain electrode 177 is disposed to be separated from the switching source electrode 176 and is connected to one capacitive plate 158.

The driving thin film transistor T2 applies driving power to the organic light emitting element E1 within the switched pixel, such as to the pixel electrode 191 thereof, where the emission layer 370 generates and emits light by the applied driving power. The first gate electrode 124 of the driving thin film transistor T2 is connected to the capacitive plate 158 connected to the switching drain electrode 177 of the switching thin film transistor T1. The second gate electrode 125 of the driving thin film transistor T2 is connected to the first gate electrode 124 thereof through a gate contact hole 113. The driving source electrode 173 and the other capacitive plate 178 are connected to the common power line 172, respectively. The driving drain electrode 175 is connected to the pixel electrode 191 through a contact hole 185.

This is described in more detail with reference to FIG. 5 and FIG. 6 as well as FIG. 4.

The first gate electrode 124 is positioned on the substrate 110. The first insulating layer 111 is positioned on the first gate electrode 124. The substrate 110 may include or be made of glass, quartz, ceramic, plastic, etc. The first insulating layer 111 may include or be made of a silicon nitride (SiNx), a silicon oxide (SiOₓ), a silicon oxynitride (SiOxNy), etc.

The driving semiconductor layer 155 is disposed or formed on the first insulating layer 111. The driving semiconductor layer 155 may include or be made of a polycrystalline silicon layer. The driving semiconductor layer 155 may include a source region 152, a channel region 153 and a drain region 154.

In this case, an upper region of the first insulating layer 111, that is, the region thereof adjacent to or closest to the driving semiconductor layer 155, is doped with fluorine (refer to FIG. 2). Accordingly, hydrogen is removed within the first insulating layer 111, and diffusion of hydrogen within the first insulating layer 111 into the driving semiconductor layer 155 is reduced or effectively prevented.

The second insulating layer 140 including or made of a silicon nitride or a silicon oxide is positioned on the driving semiconductor layer 155.

A lower region of the second insulating layer 140, that is, the region thereof adjacent to or closest the driving semiconductor layer 155, is doped with fluorine (refer to FIG. 2). Accordingly, hydrogen in the second insulating layer 140 is removed, thereby improving the reliability of the element.

The second gate electrode 125 and the first capacitive plate 158 are positioned on the second insulating layer 140. In this case, the second gate electrode 125 is positioned to overlap at least part of the driving semiconductor layer 155, in detail, the channel region 153.

Referring to FIG. 4 and FIG. 6, the first gate electrode 124 and the second gate electrode 125 are connected through or at the gate contact hole 113. That is, the display device according to the present exemplary embodiment has the dual gate structure including the first gate electrode 124 and the second gate electrode 125.

The interlayer insulating layer 160 covering the second gate electrode 125 is positioned on the second insulating layer 140. The interlayer insulating layer 160 may include or be formed of a silicon nitride or a silicon oxide similar to that for the second insulating layer 140. The second insulating layer 140 and the interlayer insulating layer 160 include the first contact hole 163 and a second contact hole 165 defined therein respectively exposing the source region 152 and the drain region 154 of the driving semiconductor layer 155.

The driving source electrode 173 and the driving drain electrode 175, the data line 171, the common power line 172, and the second capacitive plate 178 are positioned on the interlayer insulating layer 160. The driving source electrode 173 and the driving drain electrode 175 are connected to the source region 152 and the drain region 154 of the driving semiconductor layer 155 through the first contact hole 163 and the second contact hole 165, respectively.

A planarization layer 180 includes a contact hole 185 defined therein. The pixel electrode 191 is positioned on the planarization layer 180. The pixel electrode 191 is connected to the driving drain electrode 175 through or at the contact hole 185. A partition 361 is positioned on the planarization layer 180. The light emitting element E1 is positioned at an opening in the partition 361, and light is emitted from the light emitting element E1 at such opening. The emission layer 370 is positioned to overlap the pixel electrode 191 and the common electrode 270 is positioned to overlap the emission layer 370. The light emitting element E1 includes the pixel electrode 191, the emission layer 370 and the common electrode 270 which cooperate to generate and emit light.

The various layers and elements within the structures described above may be provided in plurality on the substrate 100. However, the structure described in FIG. 4 to FIG. 6 is only one example, and the structure of the display device of the invention is not limited thereto.

As described above, one or more exemplary embodiment of the thin film transistor array panel and the display device including the same according to the invention include the first gate electrode and the second gate electrode overlapping each other via the semiconductor layer and connected to each other. Also, the first insulating layer between the first gate electrode and the semiconductor layer and the second insulating layer between the second gate electrode and the semiconductor layer are each doped with fluorine, such that the hydrogen content in each respective insulating layer is thereby reduced, and diffusion of hydrogen in each of the respective insulating layers into the semiconductor layer is thereby reduced or effectively prevented. Accordingly, a breakage phenomenon of the semiconductor layer during the crystallization process of a material for forming the semiconductor layer is reduced or effectively prevented. Additionally, the hydrogen content in each layer is minimized as described above, such that the reliability of the element including such layers is improved.

What is claimed is:

1. A thin film transistor array panel comprising:
a substrate including a display area at which an image is displayed with light; and
a switching element on the substrate in the display area thereof, the switching element comprising:
a semiconductor layer;
a first gate electrode;
a second gate electrode connected to the first gate electrode;
a fluorine-doped first insulating layer between the first gate electrode and semiconductor layer; and
a fluorine-doped second insulating layer between the second gate electrode and the semiconductor layer.

2. The thin film transistor array panel of claim 1, wherein
the fluorine-doped first insulating layer and the fluorine-doped second insulating layer include a gate contact hole commonly defined therein, and
the second gate electrode is connected to the first gate electrode at the gate contact hole commonly defined in the fluorine-doped first and second insulating layers.

3. The thin film transistor array panel of claim 1, wherein
an upper region of the fluorine-doped first insulating layer which is adjacent to the semiconductor layer includes fluorine.

4. The thin film transistor array panel of claim 3, wherein
a maximum thickness of the upper region of the fluorine-doped first insulating layer which includes the fluorine is about 20% or more of an entire thickness of the fluorine-doped first insulating layer.

5. The thin film transistor array panel of claim 1, wherein
a lower region of the fluorine-doped second insulating layer which is adjacent to the semiconductor layer includes fluorine.

6. The thin film transistor array panel of claim 5, wherein
a maximum thickness of the lower region of the second insulating layer which include the fluorine is about 20% to about 100% of an entire thickness of the fluorine-doped second insulating layer.

7. The thin film transistor array panel of claim 1, wherein
the first gate electrode and the second gate electrode connected to each other overlap each other via the semiconductor layer disposed therebetween.

8. The thin film transistor array panel of claim 1, wherein
a hydrogen content of the semiconductor layer of the switching element is less than about 3 mol %.

9. The thin film transistor array panel of claim 1, wherein
the fluorine-doped first insulating layer and the fluorine-doped second insulating layer include silicon oxide or silicon nitride.

10. The thin film transistor array panel of claim 9, wherein
a doped region of the fluorine-doped first insulating layer and the fluorine-doped second insulating layer includes fluorine, and
each of the doped regions includes a silicon-hydrogen bond and a silicon-fluorine bond.

11. A display device comprising:
a substrate including a display area at which an image is displayed with light;
a switching element on the substrate in the display area thereof, the switching element comprising:
a semiconductor layer including a source region, a channel region and a drain region;
a first gate electrode;
a second gate electrode connected to the first gate electrode;
a fluorine-doped first insulating layer between the first gate electrode and the semiconductor layer;
a fluorine-doped second insulating layer between the second gate electrode and the semiconductor layer; and
a source electrode and a drain electrode connected to the source region and the drain region of the semiconductor layer, respectively; and
a first electrode of a light-generating element, connected to the drain electrode of the switching element.

12. The display device of claim 1, wherein
the fluorine-doped first insulating layer and the fluorine-doped second insulating layer include a gate contact hole commonly defined therein, and
the second gate electrode is connected to the first gate electrode at the gate contact hole commonly defined in the fluorine-doped first and second insulating layers.

13. The display device of claim 11, wherein
an upper region of the fluorine-doped first insulating layer which is adjacent to the semiconductor layer includes fluorine.

14. The display device of claim 13, wherein
a maximum thickness of the upper region of the fluorine-doped first insulating layer which includes the fluorine is about 20% or more of an entire thickness of the fluorine-doped first insulating layer.

15. The display device of claim 11, wherein
a lower region of the fluorine-doped second insulating layer which is adjacent to the semiconductor layer includes fluorine.

16. The display device of claim 15, wherein
a maximum thickness of the doped region of the fluorine-doped second insulating layer which includes the fluorine is about 20% to about 100% of an entire thickness of the fluorine-doped second insulating layer.

17. The display device of claim 11, wherein
the first gate electrode and the second gate electrode connected to each other overlap each other via the semiconductor layer disposed therebetween.

18. The display device of claim 11, wherein
a hydrogen content of the semiconductor layer of the switching element is less than about 3 mol %.

19. The display device of claim 11, further comprising:
a second electrode of the light-generating element, overlapping the first electrode of the light-generating element; and
a light emission layer which generates and emits the light, between the first electrode and the second electrode of the light-generating element.

20. The display device of claim 11, wherein
a doped region of the fluorine-doped first insulating layer and the fluorine-doped second insulating layer includes fluorine, and
each of the doped regions includes a silicon-hydrogen bond and a silicon-fluorine bond.
